(19) United States
(12) Patent Application Publication
(10) Pub. No.: US 2019/0341483 A1
(43) Pub. Date: Nov. 7, 2019

(54) SEMICONDUCTOR DEVICE

(71) Applicant: DENSO CORPORATION, Kariya-city (JP)

(72) Inventors: Syunsuke HARADA, Kariya-city (JP); Hisato KATO, Kariya-city (JP)

(21) Appl. No.: 16/513,047

(22) Filed: Jul. 16, 2019

Related U.S. Application Data
(63) Continuation of application No. PCT/JP2017/045324, filed on Dec. 18, 2017.

(30) Foreign Application Priority Data
Feb. 15, 2017 (JP) 2017-025929

(51) Int. Cl. H01L 29/78; H01L 29/08; H01L 29/417; H01L 29/06; H01L 29/423; H01L 29/10; G01R 19/10

(52) U.S. Cl. CPC H01L 29/7815; H01L 29/0869; H01L 29/41741; G01R 19/10; H01L 29/0696; H01L 29/4236; H01L 29/1095; H01L 29/7813

(57) ABSTRACT

A semiconductor device is provided on a semiconductor substrate and has a main element of a gate driven type and a sensing element for current detection disposed across an isolation region. In a configuration in a forming region of the sensing element formed on the semiconductor substrate, at least a part of a resistance component contributing to a resistance of the sensing element has a resistance value higher than a resistance value of an equivalent configuration part of a resistance component contributing to a resistance of the main element.

### CROSS REFERENCE TO RELATED APPLICATIONS

The present application is a continuation application of International Patent Application No. PCT/JP2017/045324 filed on Dec. 18, 2017, which designated the U.S. and claims the benefit of priority from Japanese Patent Application No. 2017-25929 filed on Feb. 15, 2017. The entire disclosures of all of the above applications are incorporated herein by reference.

### TECHNICAL FIELD

The present disclosure relates to a semiconductor device.

### BACKGROUND

As a semiconductor device of a gate driven type having a current detection function, there is a power semiconductor device such as a MOSFET having a configuration in which a sensing element as a current detection element is provided in addition to a main element.

### SUMMARY

The present disclosure provides a semiconductor device provided on a semiconductor substrate and having a main element of a gate driven type and a sensing element for current detection disposed across an isolation region. In a configuration in a forming region of the sensing element formed on the semiconductor substrate, at least a part of a resistance component contributing to a resistance of the sensing element has a resistance value higher than a resistance value of an equivalent configuration part of a resistance component contributing to a resistance of the main element.

### BRIEF DESCRIPTION OF DRAWINGS

The above and other objects, features and advantages of the present disclosure will become more apparent from the following detailed description made with reference to the accompanying drawings. In the drawings:

FIG. 1 is an overall plan view showing a first embodiment;

FIG. 2 is a plan view of a sensing element portion;

FIG. 3 is a cross-sectional view taken along a line III-III in FIG. 1;

FIG. 4 is a cross-sectional view taken along a line IV-IV in FIG. 2;

FIG. 5 is an equivalent circuit diagram;

FIG. 6 is an illustrative diagram of a resistance component;

FIG. 7 is an electrical characteristic diagram (part 1);

FIG. 8 is an electrical characteristic diagram (part 2);

FIG. 9 is an electrical characteristic diagram (part 3);

FIG. 10 is an electrical characteristic diagram (part 4);

FIG. 11 is a plan view of a sensing element portion according to a second embodiment;

FIG. 12 is a cross-sectional view taken along a line XII-XII in FIG. 11;

FIG. 13 is a plan view of a sensing element portion according to a third embodiment;

FIG. 14 is a cross-sectional view taken along a line XIV-XIV in FIG. 13;

FIG. 15 is a plan view of a sensing element portion according to a fourth embodiment;

FIG. 16 is a cross-sectional view taken along a line XVI-XVI in FIG. 15;

FIG. 17 is a cross-sectional view of a main element and a sensing element portion according to a fifth embodiment;

FIG. 18 is a cross-sectional view of a main element and a sensing element portion according to a sixth embodiment;

FIG. 19 is a cross-sectional view of a main element and a sensing element portion according to a seventh embodiment;

FIG. 20 is a cross-sectional view of a main element and a sensing element portion according to an eighth embodiment;

FIG. 21 is an electrical characteristic diagram (part 5);

FIG. 22 is a cross-sectional view of a main element and a sensing element portion according to a ninth embodiment;

FIG. 23 is a cross-sectional view of a main element and a sensing element portion according to a tenth embodiment;

FIG. 24 is a cross-sectional view of a main element and a sensing element portion according to an eleventh embodiment;

FIG. 25 is a plan view of a sensing element portion according to a twelfth embodiment; and

FIG. 26 is a cross-sectional view taken along a line XXVI-XXVI in FIG. 25.

### DETAILED DESCRIPTION

In some semiconductor devices, a sensing element as a current detection element is provided in addition to a main element of a gate driven type. The sensing element has a configuration comparable to a configuration of the main element, allows a current proportional to a current of the main element to flow, and detects the current to detect the current of the main element.

In such semiconductor devices, there is an issue that a sensing ratio between the current detected by the sensing element and the current of the main element varies depending on a gate voltage and a temperature characteristic, and the current of the main element cannot be accurately detected. In this case, for example, since the sense current flows into an isolation region between the main element and the sensing element to increase the current of the sensing element, the sensing ratio may be lowered.

According to a first aspect of the present disclosure, a semiconductor device is to be provided on a semiconductor substrate and has a main element of a gate driven type and a sensing element for current detection disposed across an isolation region. In a configuration of the sensing element and the isolation region formed on the semiconductor substrate, at least a part of a resistance component contributing to a resistance of the sensing element has a resistance value higher than a resistance value of an equivalent configuration part of a resistance component contributing to a resistance of the main element.

With the employment of the configuration described above, when the current of the main element is detected by the sensing element, since the resistance of the sensing element is formed to be higher than the resistance of the main element, even when the current of the sensing element spreads toward the isolation region when the gate voltage becomes large and the substantial resistance of the sensing element portion becomes small, the resistance of the sensing element can be comparable to the resistance of the main element as a result. Accordingly, a variation in the sensing ratio can be reduced even in the region where the current becomes large, and the variation in the sensing ratio can be reduced in a wide range of the gate voltage.

### First Embodiment

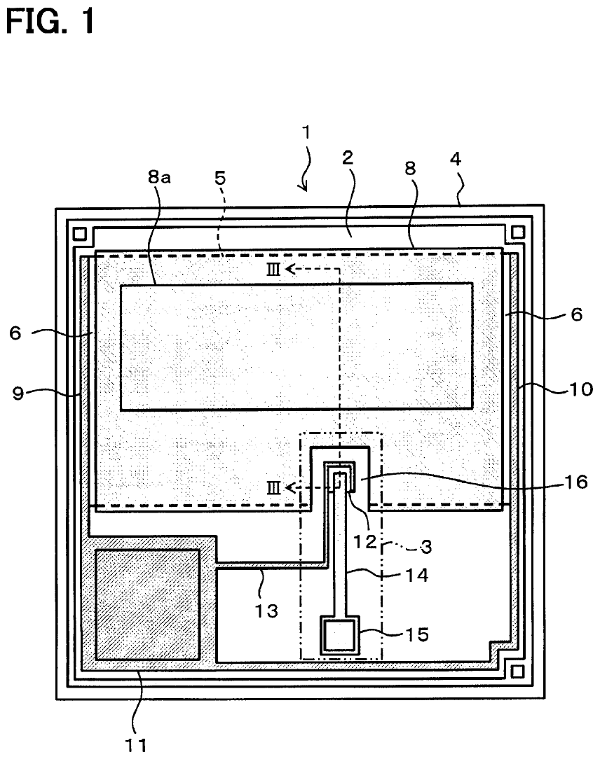

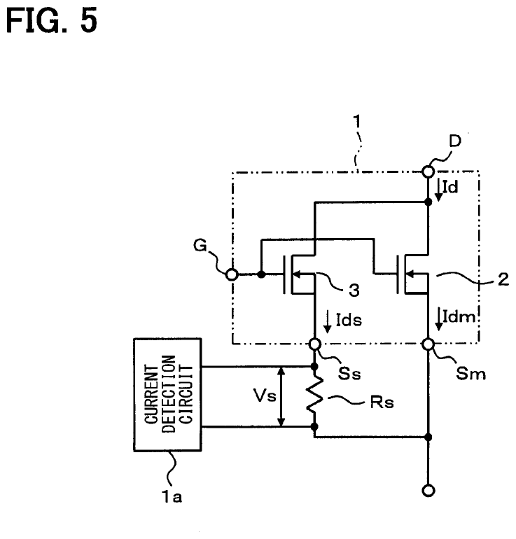

Hereinafter, a first embodiment will be described with reference to FIGS. 1 to 10. In the present embodiment, a case in which a semiconductor device is applied to a power MOSFET 1 will be described. As shown in an equivalent circuit of FIG. 5, the MOSFET 1 includes a main element 2 and a sensing element 3 for detecting a current. The main element 2 and the sensing element 3 are designed so that drain currents of the main element 2 and the sensing element 3 become a predetermined current ratio that is a sensing ratio at a predetermined level. This is formed by setting source areas of the main element 2 and the sensing element 3 to a ratio corresponding to the sensing ratio.

Drains and gates of the main element 2 and the sensing element 3 are a common drain D and a common gate G. A source of the main element 2 is a terminal S, and a source of the sensing element 3 is a terminal Sa. The source Sa of the sensing element 3 is commonly connected to the terminal S through a resistor Rs for current detection in series. An inter-terminal voltage Vs of the resistor Rs is detected by a current detection circuit 1 a to detect a current Ids of the sensing element 3. A drain current Idm of the main element 2 can be detected by multiplying the sensing ratio based on the current of the sensing element 3.

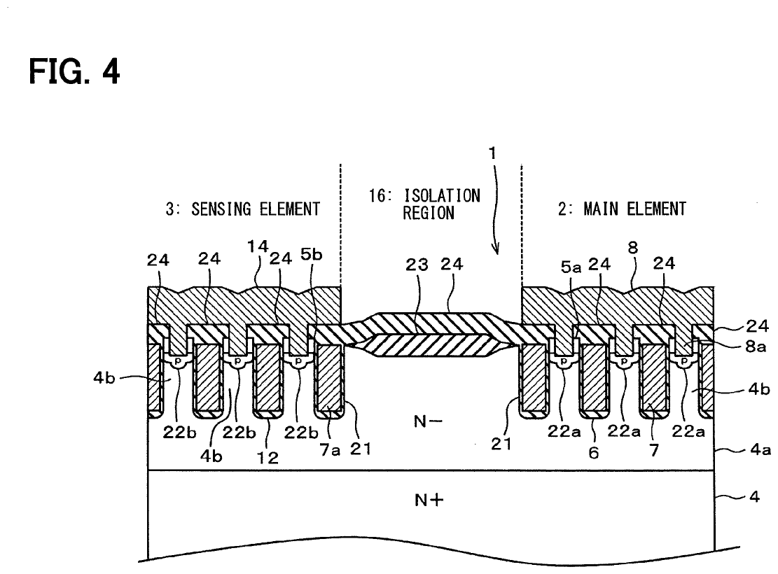

FIG. 1 is a plan view illustrating an overall layout of the MOSFET 1, in which a semiconductor substrate 4 having a rectangular shape is disposed with an oblong source region 5 of the main element 2 from a top to a center. A gate pattern 6 is formed to cover the source region 5. Multiple gate patterns 6 are formed on the source region 5 in a line shape in a lateral direction in the figure at predetermined intervals. The gate patterns 6 are formed with gate electrodes 7 (refer to FIG. 4) covered inside each line with an insulating film, as will be described below.

A rectangular source electrode 8 corresponding to the source region 5 is formed on an upper surface of the gate patterns 6. Gate lead-out patterns 9 and 10 made of a metal film formed along a periphery of the semiconductor substrate 4 are disposed at both ends of the gate patterns 6 so as to be electrically connected to the respective gate electrodes 7. The gate lead-out patterns 9 and 10 are electrically connected to a gate pad 11 provided in a lower left area of the semiconductor substrate 4 in the drawing. A rectangular region in which the gate pattern 6 is not formed is provided in a part of a lower side portion of the source region 5, and the sensing element 3 is disposed inside the rectangular region. A source region 8 similar to the source region 5 is formed in the sensing element 3.

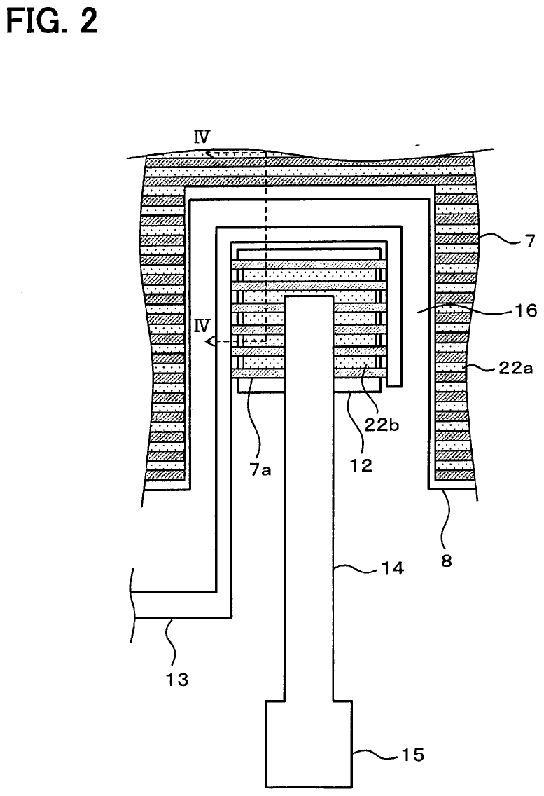

As shown in FIG. 2, the sensing element 3 is provided with a gate pattern 12 on which a gate electrodes 7a similar to the gate electrodes 7 are formed. The gate pattern 12 is provided with a gate lead-out pattern 13 electrically connected to the gate electrodes 7a on the right and left, and coupled with each other on an upper portion is placed so as to electrically connect to the gate pad 11. A source electrode 14 electrically connected to the source region is formed on an upper surface of the sensing element 3, and is patterned so as to be connected to a sense source pad 15 provided on a lower side of the semiconductor substrate 4. A boundary portion between the sensing element 3 and the main element 2 is defined as an isolation region 16, and a LOCOS (Local Oxidation of Silicon) film 23 is formed on a surface portion of the isolation region 16 as shown in FIG. 4.

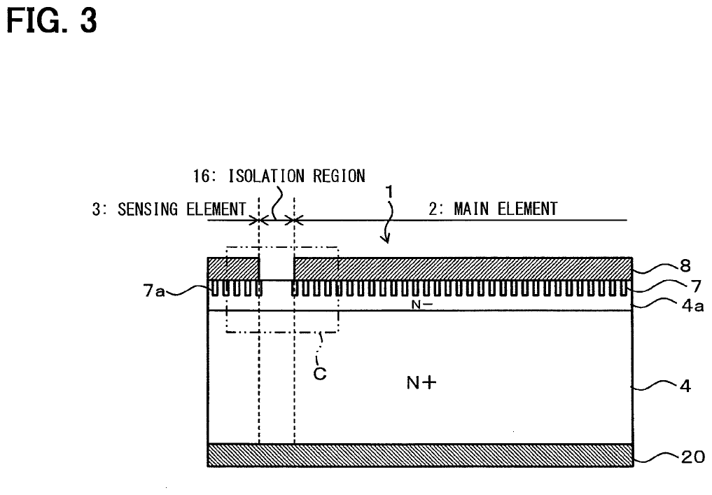

Reference is now made to FIG. 3, which shows a cross section of a portion taken along a line III-III in FIG. 1, and FIG. 4, which shows a cross section of a portion taken along a line IV-IV in FIG. 2. The semiconductor substrate 4 is formed of, for example, a silicon substrate into which N-type impurities are introduced at a high concentration (N+), and a high-resistance epitaxial layer 4a into which N-type impurities are introduced at a low concentration (N−) is formed on an upper surface. The multiple gate electrodes 7 are buried in a surface layer portion of the epitaxial layer 4a at predetermined intervals. An isolation region 16 in which the gate electrodes 7 and 7a are not formed is provided between the main element 2 and the sensing element 3. On a lower surface side of the semiconductor substrate 4, a common drain electrode 20 of the main element 2 and the sensing element 3 is formed with a predetermined film thickness over the entire surface.

The gate pattern 6 of the main element 2 and the gate pattern 12 of the sensing element 3 respectively define multiple trenches provided in the epitaxial layer 4a up to a predetermined depth and are formed inside the trenches. An insulating film 21 is formed on a bottom surface and side wall surfaces inside each trench, and gate electrodes 7 and 7a are formed in an inner region of the insulating film 21. Therefore, the gate electrodes 7 and 7a are formed so as to face an epitaxial layer 4a across the insulating film 21 serving as a gate insulating film.

As described above, in the epitaxial layer 4a, channel regions 22a and 22b formed by introducing P-type impurities are formed in upper surface portions of regions 4b between the gate electrodes 7 and the gate electrodes 7a provided by the gate patterns 6 and 12, respectively. In the present embodiment, in FIG. 4, the channel regions 22a are formed in the main element 2, and the channel regions 22b are formed in the sensing element 3. The two channel regions 22a and 22b are formed so as to have different impurity concentrations, so that the resistance value of the channel regions 22b become higher than the resistance value of the channel regions 22a in terms of unit area.

The LOCOS film 23 is formed on the surface of the isolation region 16 so as to cover the surface as described above, and the main element 2 and the sensing element 3 are isolated from each other. An insulating film 24 is formed so as to cover the upper surfaces of the LOCOS film 23 and the gate electrodes 7 and 7a. As described above, the gate electrodes 7 and 7a are processed so as to be connected to the gate lead-out patterns 9, 10, or 13 at ends of the gate electrodes 7 and 7a. N-type source regions 5a and 5b into which N-type impurities are introduced at a high concentration (N+) are formed on upper portions of the channel regions 22a and 22b. The source electrode 8 in the main element 2 is formed so as to be in electrical contact with the source regions 5a and the channel regions 22a, and is connected at the upper surface portion through the insulating film 24. The source electrode 14 in the sensing element 3 is formed so as to be in electrical contact with the sources 5b and the channel regions 22b, and is connected at the upper surface portion through the insulating film 24.

In the above configuration, in the main element 2, one main cell is configured by the region 4b of the epitaxial layer 4a, the channel region 22a, and the source region 5a in a region sandwiched between the two gate electrodes 7. In the multiple main cells, when a gate voltage is applied to the gate electrode 7, a channel is provided in the channel region 22a, and the source region 5a and the region 4b serving as a drain are rendered conductive.

In the sensing element 3, one sense cell is formed by the region 4b of the epitaxial layer 4a, the channel region 22b, and the source region 5b in a region sandwiched between the two gate electrodes 7a. In the multiple sense cells, when a gate voltage is applied to the gate electrode 7a, a channel is provided in the channel region 22b, and the source region 5b and the region 4b serving as a drain are rendered conductive. The region 4b functions as a drift region.

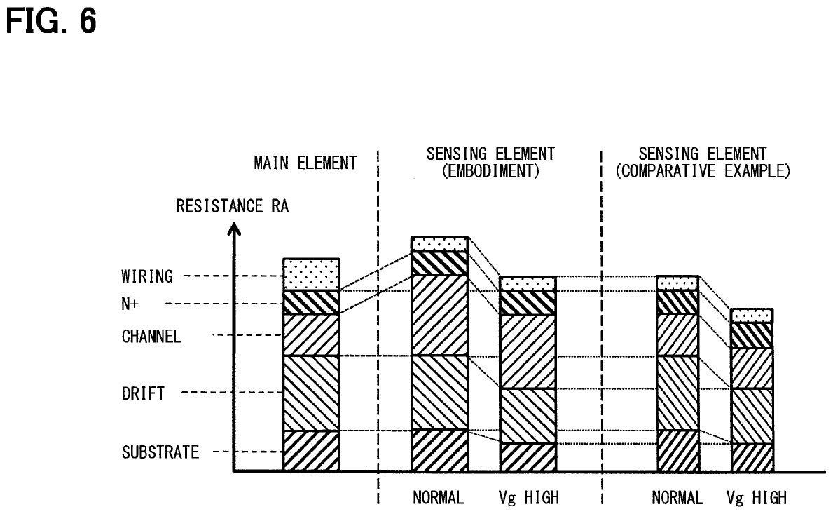

In that case, in the sense cell of the sensing element 3, since the channel region 22b is formed to have the resistance higher than the resistance of the channel region 22a of the main cell, the resistance is higher than the resistance of the main cell per unit area in a conductive state, that is, in an on-state. FIG. 6 shows a comparison of the case where a resistance R of the main element 2 and the sensing element 3 is normalized as a value RA per unit area. The RA of the main element 2 and the sensing element 3 is a combined resistance such as a substrate resistance, a drift resistance, a channel resistance, a source region (N+ region) resistance, and a resistance of the wiring pattern.

In FIG. 6, a case where resistance components of the resistance RA of the main element 2 are configured as shown in the figure will be described. In a comparative example, the resistance RA of the sensing element 3 is substantially the same as the resistance RA of the main element 2 in a normal use mode. However, the resistance RA of the sensing element 3 varies depending on the usage state of the main element 2.

In other words, in a state where the gate voltage is high (Vg is high), as shown in FIG. 8, a part of the current flowing through the sensing element spreads toward an isolation region in the channel region, the drift region, and the substrate region, which are components of the resistance RA, and therefore, a cross-sectional area through which the current flows is widened as a whole. FIG. 8 shows a current of the sensing element 3 as a path obtained from a density distribution. As a result, in the sensing element 3 of the comparative example, the resistance R is substantially lowered, and becomes relatively smaller than the resistance RA of the main element 2. As a result, in a region where the current of the main element 2 is large, the resistance RA of the sensing element 3 is lowered, so that the sensing ratio is lowered.

On the other hand, in the sensing element 3 of the present embodiment, in consideration of the above point, the impurity concentration of the channel region 22b is adjusted in advance so as to increase the channel resistance component. As a result, as shown in FIG. 6, the channel resistance component is large in the normal usage state, but when the gate voltage Vg is large, the channel resistance component can be made substantially equal to the resistance RA of the main element 2.

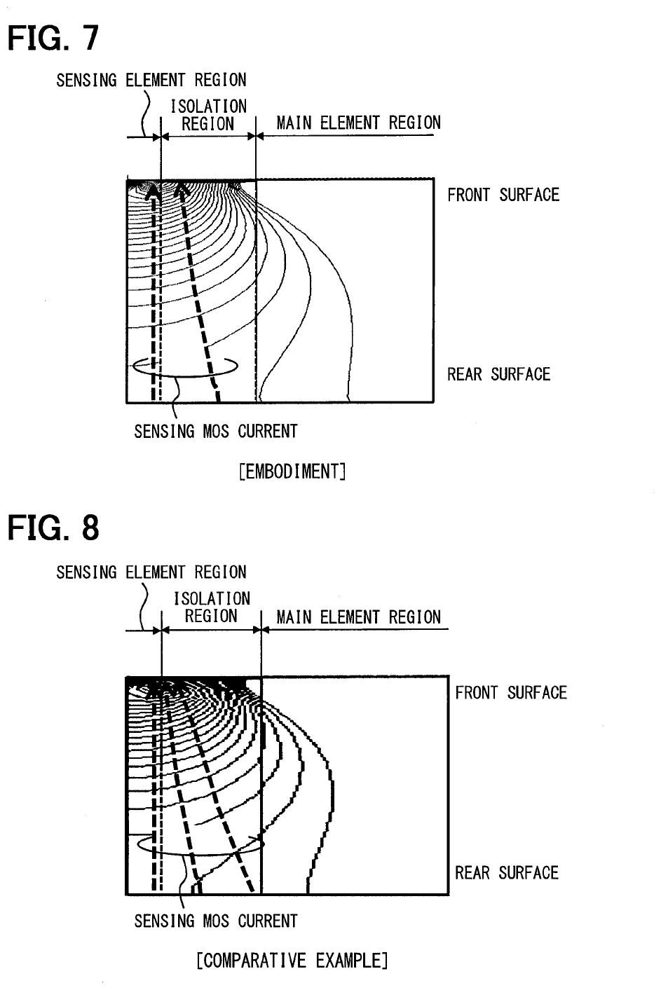

As a result, in the sensing element 3 according to the present embodiment, the resistance RA is slightly larger than the resistance RA of the main element 2 in the normal usage state, but the resistance RA can be substantially the same at the high current level flowing when the gate voltage Vg is set to be large. Accordingly, since the conditions can be comparable to conditions of the main element 2 at a position where the influence of the voltage drop due to the resistor RA becomes large at a large current, a variation of the current ratio, that is, the sensing ratio can be reduced as a whole. As shown in FIG. 7, the above state is comparable to a state in which a current path obtained from a current density does not substantially spread to the isolation region 16.

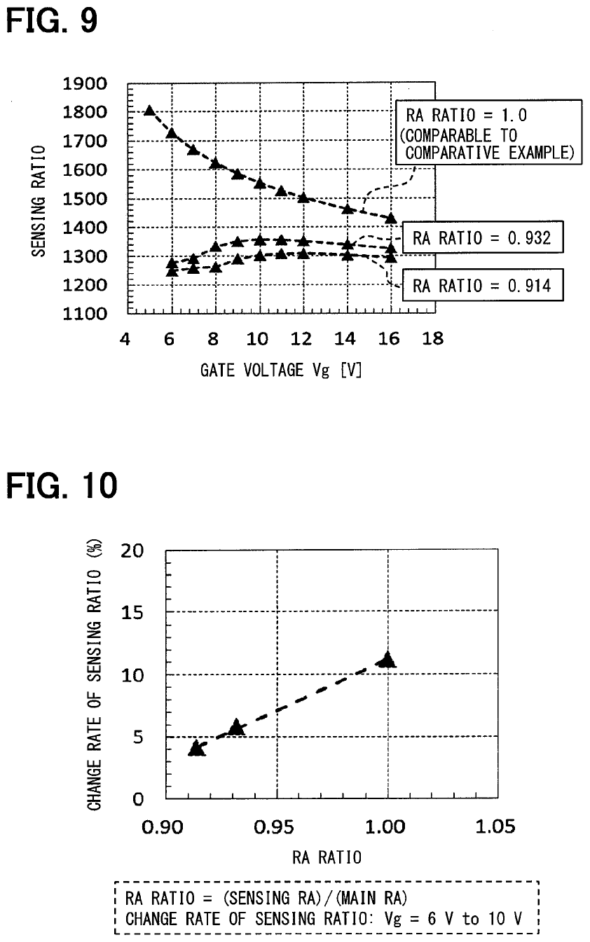

Next, electrical characteristics in the case of adopting the above configuration will be described with reference to FIGS. 9 and 10. FIG. 9 shows the result of plotting a sensing ratio to a gate voltage Vg, that is, a ratio of a drain current of the sensing element to the drain current of the main element 2 on a vertical axis, with the gate voltage Vg taken as the horizontal axis by simulation. In the present embodiment, the resistance RA of the sensing element 3 at a normal current level which is not affected by the spread of the current is set to what extent is set as the RA ratio with respect to the resistance RA of the main element 2, and the result when a value of the RA ratio is changed is shown.

In FIG. 9, for comparison, a sensing ratio comparable to the comparative example in which the RA ratio is set to “1” is plotted. In this example, when the RA ratio is set to “0.932” or set to about “0.914”, it can be confirmed that a variation in the sensing ratio is small over a wide range of the gate voltage Vg.

In FIG. 10, the above relationship is plotted from the viewpoint of a change rate of the sensing ratio. When the RA ratio is taken on the horizontal axis and the change rate the sensing ratio is taken on the vertical axis, it can be confirmed that the change rate occurs at 10% or more when the RA ratio comparable to the comparative example is “1” whereas the rate of the change can be reduced to about 5% or less by setting the RA ratio at about “0.935” or less. In this example, the change rate of the sensing ratio when the gate voltage Vg is set to 6 to 10 V is obtained.

As a result, it has been found that the change rate of the sensing ratio also tends to be lowered by lowering the RA ratio. In addition, from the results shown in FIG. 9, it found that with a reduction in the RA ratio, the sensing ratio also tended to be lowered. In practical use, since there is a need to secure a certain degree of sensing ratio, when the RA ratio is set under the setting condition of what percentages or less the change rate of the sensing ratio should be reduced to, a design can be performed under an effective condition.

According to the present embodiment, with the employment of a configuration in which the resistance value of the channel region 22b of the sensing element 3 is set to be higher than the resistance value of the channel region 22a of the main element 2, a stable MOSFET 1 which reduces the variation in sensing ratio can be obtained.

In addition, as the degree of increasing the resistance value of the channel region 22b of the sensing element 3, the resistance value is set to a range from about “0.94” to “0.91” in consideration of the RA ratio, thereby being capable of setting the change rate of the sensing ratio to about 5%.

### Second Embodiment

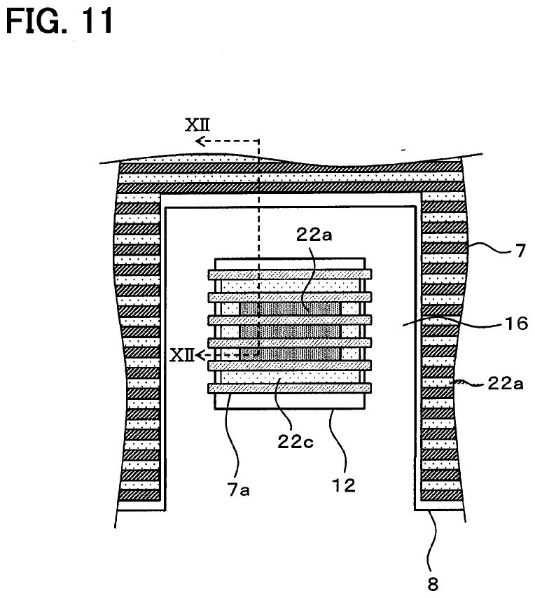

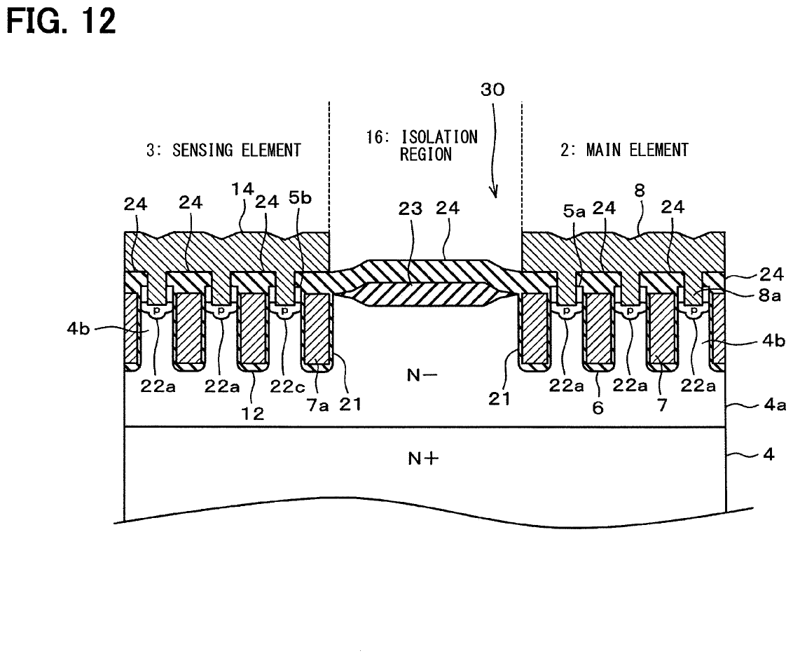

FIGS. 11 and 12 show a second embodiment, and different portions from the first embodiment will be described below. In the present embodiment, in a MOSFET 30 as a semiconductor device, a channel region 22c is provided in place of a channel region 22b of a sensing element 2.

The channel region 22c is adjusted by introducing an impurity so as to have a high resistance similarly to the channel region 22b shown in the first embodiment. Further, as shown in FIG. 11, the channel region 22c is a pattern provided in a cell portion of a peripheral portion with respect to a rectangular planar pattern of the sensing element 3, and a central portion is set to an impurity concentration comparable to an impurity concentration of the channel region 22a of the main element 2. In FIG. 11, a source electrode 14 is omitted.

As a result, as shown in FIG. 12, the channel region 22c located between one gate electrode 7a in contact with an isolation region 16 in a region of the sensing element 3 and another gate electrode 7a adjacent to the inside of the one gate electrode 7a is formed to have a high resistance, and the channel regions 22a located on the inside of the channel region 22c are set to have a resistance comparable to the resistance of the main element 2.

Even with the configuration described above, similarly to the first embodiment, with the employment of a configuration in which the resistance value of the channel region 22c located in the peripheral portion of the sensing element 3 is set to be higher than the resistance value of the channel regions 22a of the main element 2, a stable MOSFET 30 reducing the variation in the sensing ratio can be obtained.

### Third Embodiment

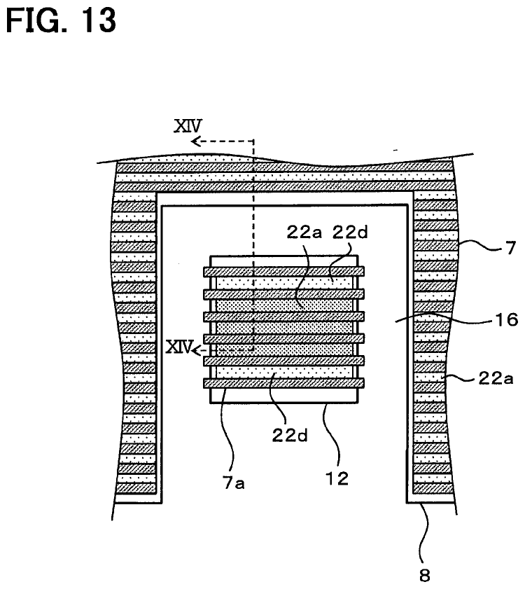

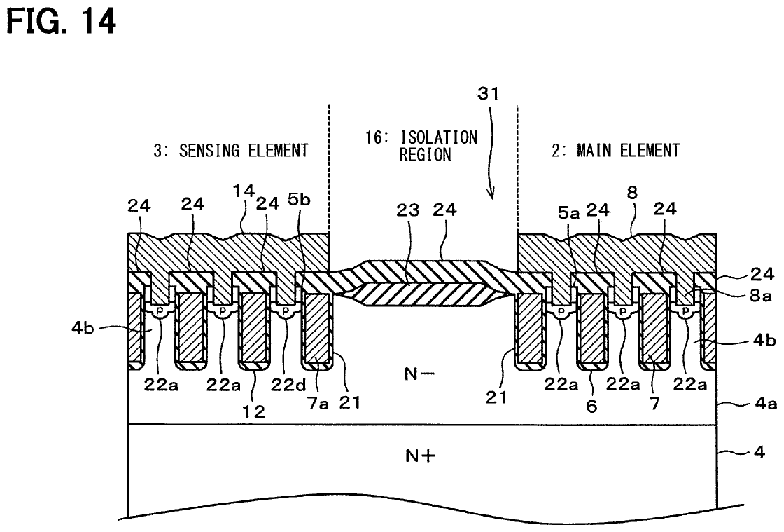

FIGS. 13 and 14 show a third embodiment, and different portions from the first embodiment will be described below. In the present embodiment, in a MOSFET 31 as a semiconductor device, channel regions 22d are provided in place of the channel regions 22b of the sensing element 2.

The channel regions 22d are adjusted by introducing an impurity so as to have a high resistance similarly to the channel regions 22b shown in the first embodiment. In addition, as shown in FIG. 13, the channel regions 22d are patterns provided in a cell portion of upper and lower sides facing a rectangular planar pattern of the sensing element 3, and regions located in the left and right sides are set to have an impurity concentration comparable to an impurity concentration of the channel region 22a of the main element 2.

As a result, as shown in FIG. 14, the channel region 22d located between one gate electrode 7a in contact with an isolation region 16 in a region of the sensing element 3 and another gate electrode 7a located on the inside of the one gate electrode 7a is formed to have a high resistance, and the channel regions 22a located on the inside of the channel region 22c are set to have a resistance comparable to the resistance of the main element 2.

Even with the configuration described above, similarly to the first embodiment, with the employment of a configuration in which the resistance value of the channel region 22d located in the peripheral portion of the sensing element 3 is set to be higher than the resistance value of the channel regions 22a of the main element 2, a stable MOSFET 31 reducing the variation in the sensing ratio can be obtained.

### Fourth Embodiment

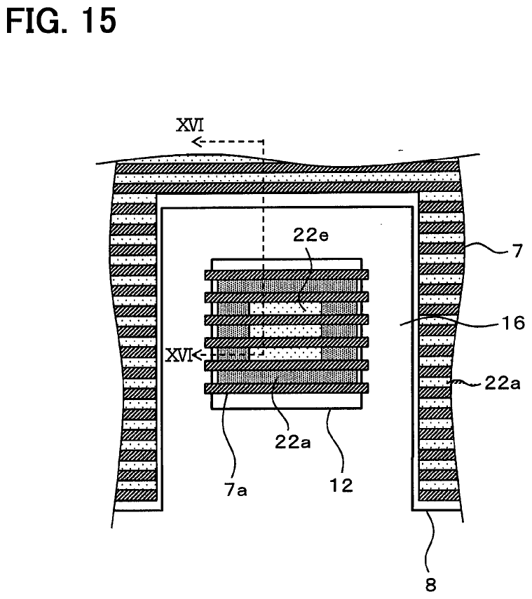

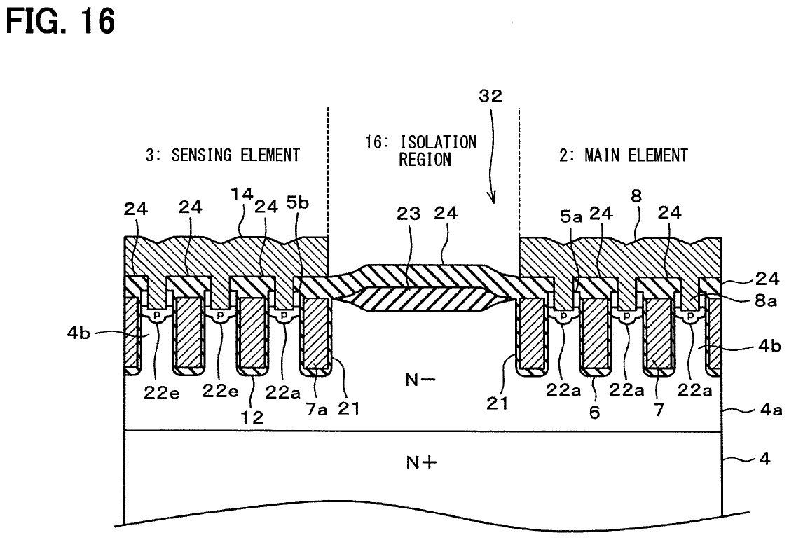

FIGS. 15 and 16 show a fourth embodiment, and different portions from the first embodiment will be described below. In the present embodiment, in a MOSFET 32 as a semiconductor device, channel regions 22e are provided in place of the channel regions 22b of the sensing element 2.

The channel regions 22e are adjusted by introducing an impurity so as to have a high resistance similarly to the channel regions 22b shown in the first embodiment. In addition, as shown in FIG. 15, the channel regions 22e are patterns provided in a cell portion in a region located on an inner side of a rectangular planar pattern of the sensing element 3, and a region in a peripheral portion is set to have an impurity concentration comparable to an impurity concentration of the channel region 22a of the main element 2.

As a result, as shown in FIG. 16, the channel region 22a located between one gate electrode 7a in contact with an isolation region 16 in a region of the sensing element 3 and another gate electrode 7a located on the inside of the one gate electrode 7a is set to have a resistance comparable to that of the main element 2, and the channel regions 22e located on the inside of the channel region 22a are set to have a high resistance.

Even with the configuration described above, similarly to the first embodiment, with the employment of a configuration in which the resistance value of the channel region 22e located in the center of the sensing element 3 is set to be higher than the resistance value of the channel regions 22a of the main element 2, a stable MOSFET 32 reducing the variation in the sensing ratio can be obtained.

### Fifth Embodiment

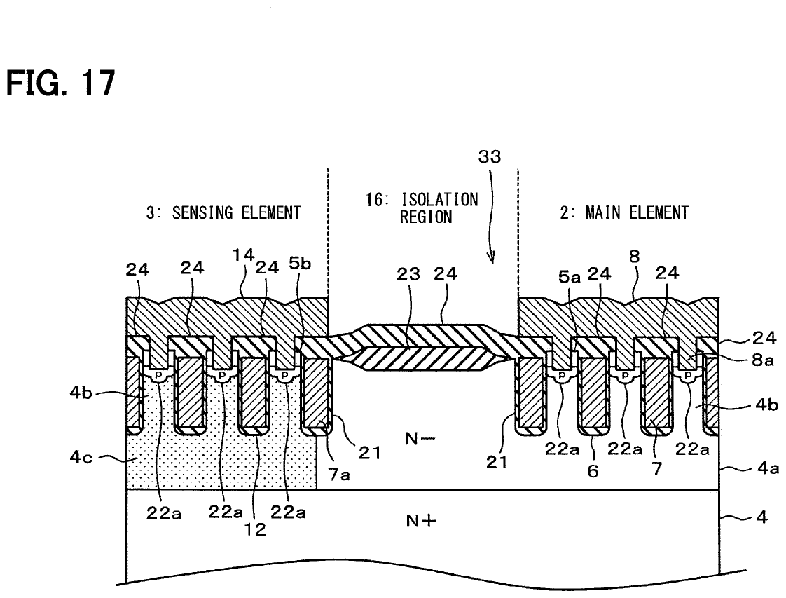

FIG. 17 shows a fifth embodiment, and portions different from the first embodiment will be described below. In the present embodiment, as an MOSFET 33 of a semiconductor device, channel regions 22b of a sensing element 2 does not have a high resistance but are channel regions 22a having the same impurity concentration as the channel regions 22a of a main element 2. On the other hand, the impurity concentration is adjusted so as to increase a resistance value of a portion of an epitaxial layer 4a in a region 4c corresponding to the sensing element 3. As a result, instead of forming the high resistance as the channel region 22b in the first embodiment, a region 4c of the epitaxial layer 4a can be configured as a high resistance region.

Even with the configuration described above, similarly to the first embodiment, a resistance RA of the sensing element 3 can be set to be higher than the resistance RA of the main element 2, thereby being capable of obtaining a stable MOSFET 33 reducing a variation in the sensing ratio.

### Sixth Embodiment

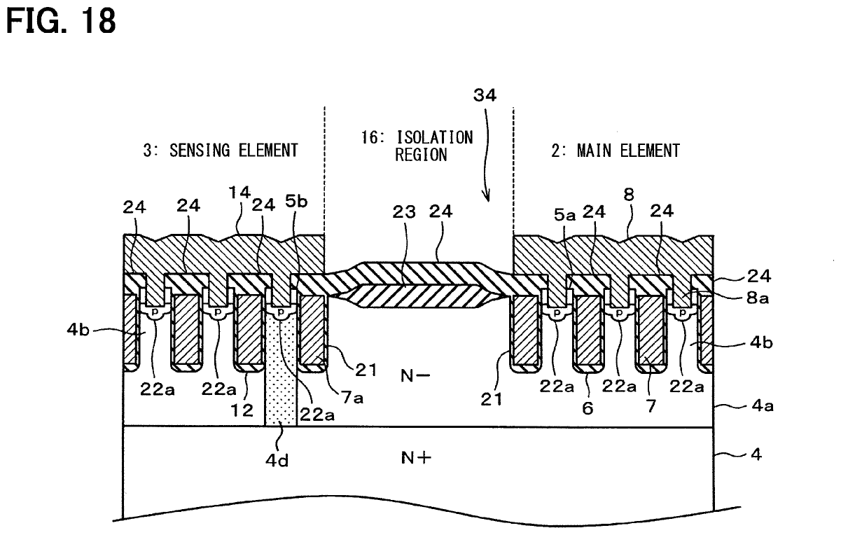

FIG. 18 shows a sixth embodiment, and portions different from the fifth embodiment will be described below. In the present embodiment, a high-resistance region 4d is provided in place of a region 4c of an epitaxial layer 4a of a sensing element 2 as a MOSFET 34 of the semiconductor device. The region 4d of the epitaxial layer 4a is the same region as the channel region 22c of FIG. 11 shown in the second embodiment, that is, a region located in a peripheral portion of the sensing element 3 is adjusted in concentration of impurities so as to have a high resistance.

Even with the configuration described above, similarly to the fifth embodiment, a resistance RA of the sensing element 3 can be set to be higher than the resistance RA of the main element 2, thereby being capable of obtaining a stable MOSFET 34 reducing a variation in the sensing ratio.

In the present embodiment, the same operation and effects can be obtained by setting the epitaxial layer 4a of a portion corresponding to the same region as the channel region 22d of FIG. 13 shown in the third embodiment to be high in resistance.

### Seventh Embodiment

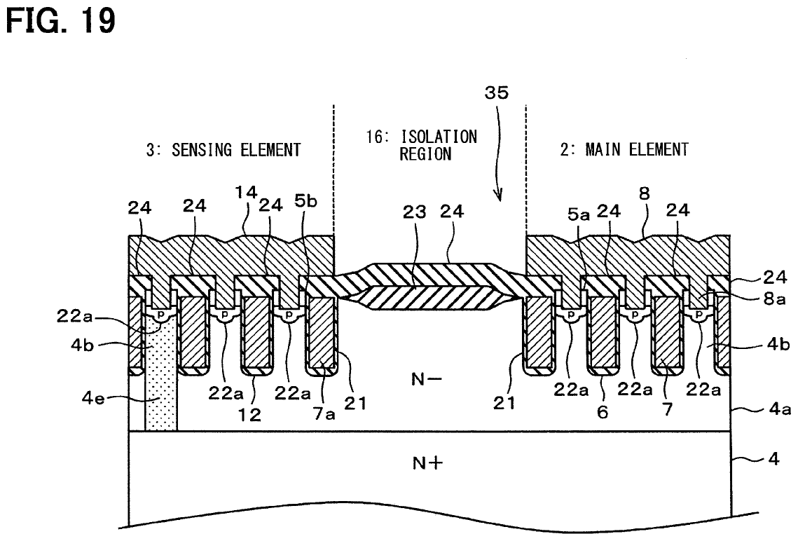

FIG. 19 shows a seventh embodiment, and portions different from the fifth embodiment will be described below. In the present embodiment, a high-resistance region 4e is provided in place of the region 4c of the epitaxial layer 4a of the sensing element 2 as a MOSFET 35 of a semiconductor device. The region 4e of the epitaxial layer 4a is the same region as the channel region 22e of FIG. 15 shown in the fourth embodiment, that is, a region located in the center of the sensing element 3 is adjusted in concentration of impurities so as to have a high resistance.

Even with the configuration described above, similarly to the fifth embodiment, a resistance RA of the sensing element 3 can be set to be higher than the resistance RA of the main element 2, thereby being capable of obtaining a stable MOSFET 35 reducing a variation in the sensing ratio.

### Eighth Embodiment

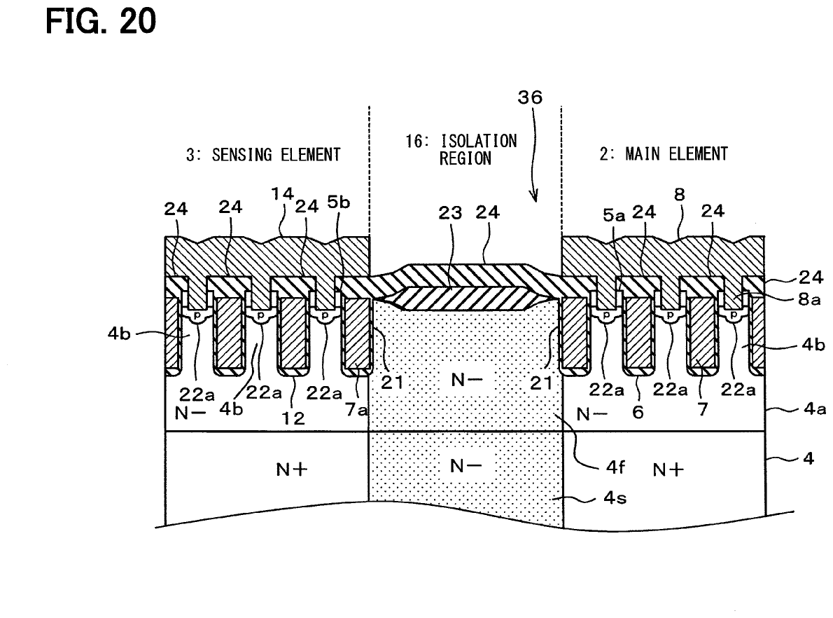

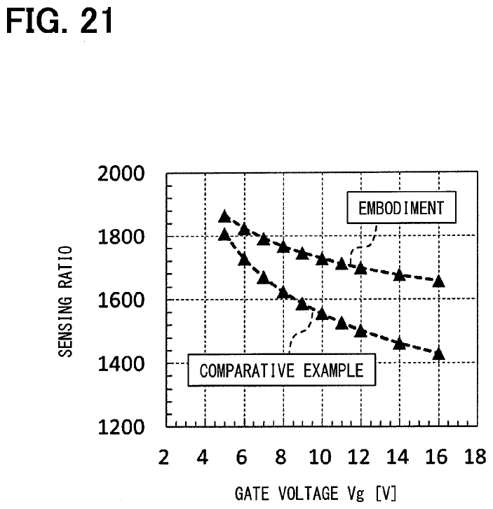

FIGS. 20 and 21 show an eighth embodiment, and different portions from the first embodiment will be described below. In the present embodiment, as an MOSFET 36 of a semiconductor device, a main element 2 and a sensing element 3 are configured to provide channel regions 22a having the same resistance value, and an epitaxial layer 4a and a semiconductor substrate 4 of an isolation region 16 are configured to provide a region 4f and a region 4s having high resistance values, respectively.

Specifically, in the region 4f of the epitaxial layer 4a and the region 4s of the semiconductor substrate 4, the impurity concentration is adjusted, the resistance values of the regions 4f and 4s of the isolation region 16 are formed to be higher than a resistance value of a comparable portion of the sensing element 3.

According to the configuration described above, a current of the sensing element 3 is less likely to spread toward the isolation region 16, and a substantial decrease in the resistance RA can be reduced. As a result, as shown in FIG. 21, even when a gate voltage Vg enters a high region of about 5V to 16V, a decrease of the sensing ratio can be reduced. FIG. 21 shows the comparative example in which the sensing ratio tends to decrease, and it is understood that the decrease in the sensing ratio can be reduced.

### Ninth Embodiment

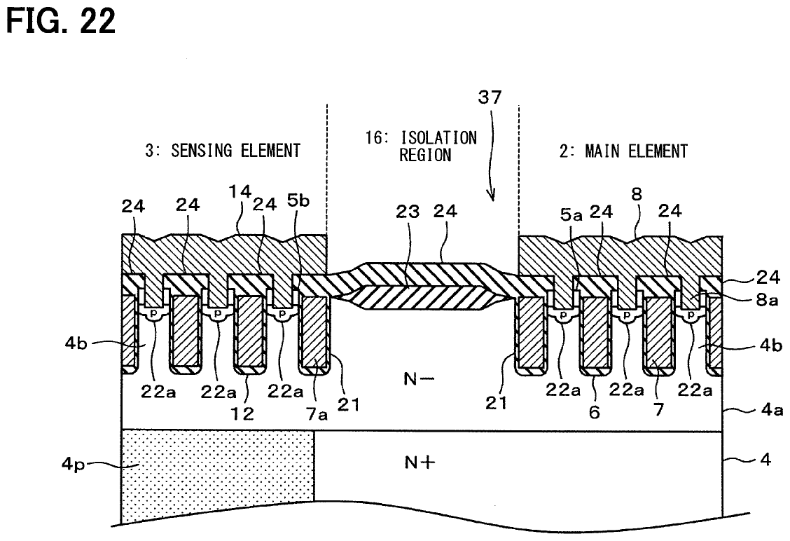

FIG. 22 shows a ninth embodiment, and portions different from the first embodiment will be described below. In the present embodiment, as an MOSFET 37 of a semiconductor device, channel regions 22b of a sensing element 2 are not high-resistance but are channel regions 22a having the same impurity concentration as the channel regions 22a of the main element 2. On the other hand, the concentration of the N-type impurity is adjusted so as to increase a resistance value of a portion of a region 4p serving as a drain corresponding to a sensing element 3 of a semiconductor substrate 4. As a result, instead of forming the high resistance as the channel region 22b in the first embodiment, the region 4p of the semiconductor substrate 4 can be configured as a high resistance region.

Even with the configuration described above, similarly to the first embodiment, the resistance RA of the sensing element 3 can be set to be higher than the resistance RA of the main element 2, thereby being capable of obtaining a stable MOSFET 37 reducing a variation in the sensing ratio.

### Tenth Embodiment

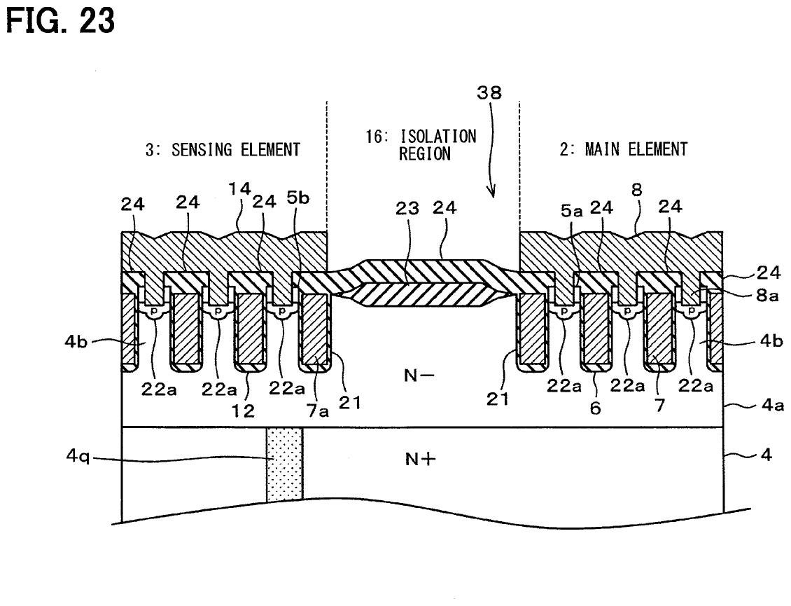

FIG. 23 shows a tenth embodiment, and portions different from the ninth embodiment will be described below. In the present embodiment, as a MOSFET 38 which is a semiconductor device, a high-resistance region 4q is provided in place of a region 4p of a semiconductor substrate 4 of a sensing element 2. The region 4q of the semiconductor substrate 4 functions as a drain, and is a region similar to the channel region 22c of FIG. 11 shown in the second embodiment, that is, a portion located in a peripheral portion of the sensing element 3 is adjusted in the concentration of impurities so as to have a high resistance.

Even with the configuration described above, similarly to the ninth embodiment, the resistance RA of the sensing element 3 can be set to be higher than the resistance RA of the main element 2, thereby being capable of obtaining a stable MOSFET 38 reducing a variation in the sensing ratio.

In the present embodiment, the same operation and effects can be obtained by setting the semiconductor substrate 4 in a portion corresponding to the same region as the channel region 22d of FIG. 13 shown in the third embodiment to be high in resistance.

### Eleventh Embodiment

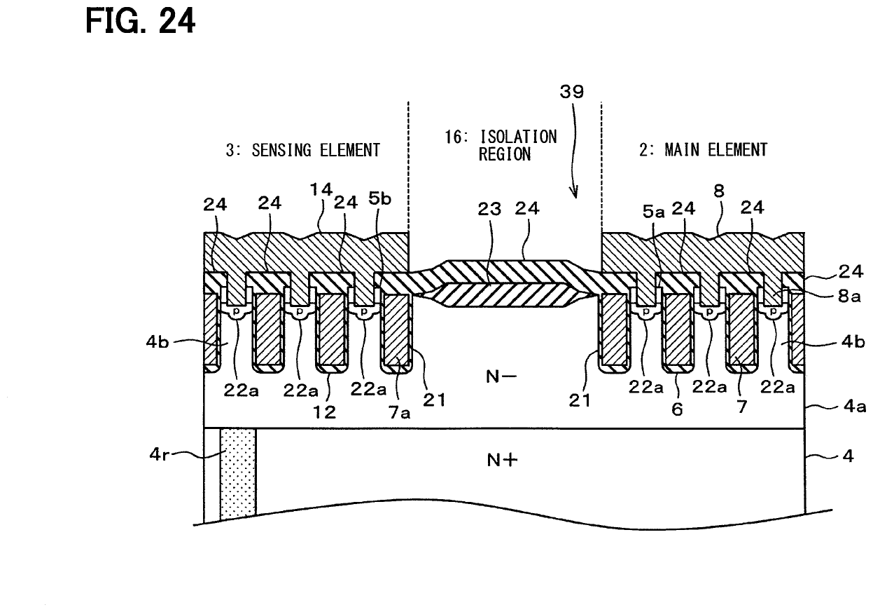

FIG. 24 shows an eleventh embodiment, and portions different from the ninth embodiment will be described below. In the present embodiment, as a MOSFET 39 which is a semiconductor device, a high-resistance region 4r is provided in place of the region 4p of the semiconductor substrate 4 of the sensing element 2. The region 4r of the semiconductor substrate 4 is the same region as the channel region 22e of FIG. 15 shown in the fourth embodiment, that is, a portion located in the center of the sensing element 3 is adjusted in concentration of impurities so as to have a high resistance.

Even with the configuration described above, similarly to the ninth embodiment, the resistance RA of the sensing element 3 can be set to be higher than the resistance RA of the main element 2, thereby being capable of obtaining a stable MOSFET 39 reducing a variation in the sensing ratio.

### Twelfth Embodiment

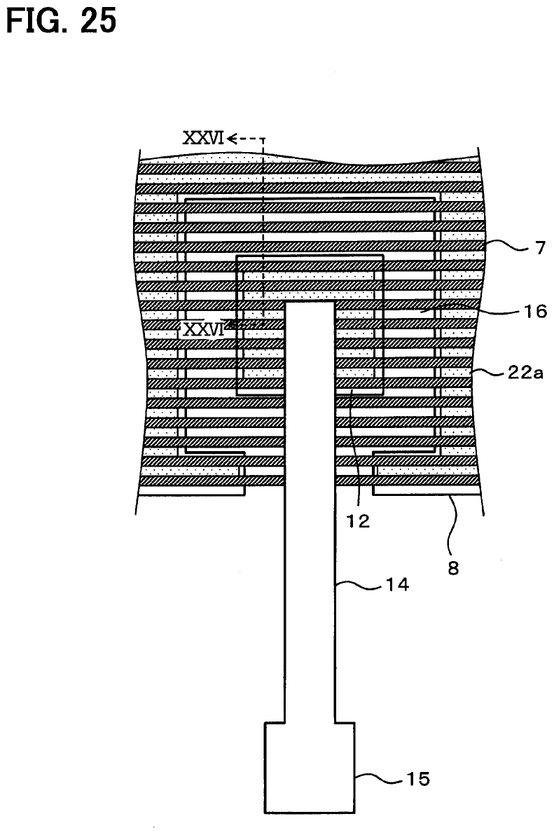

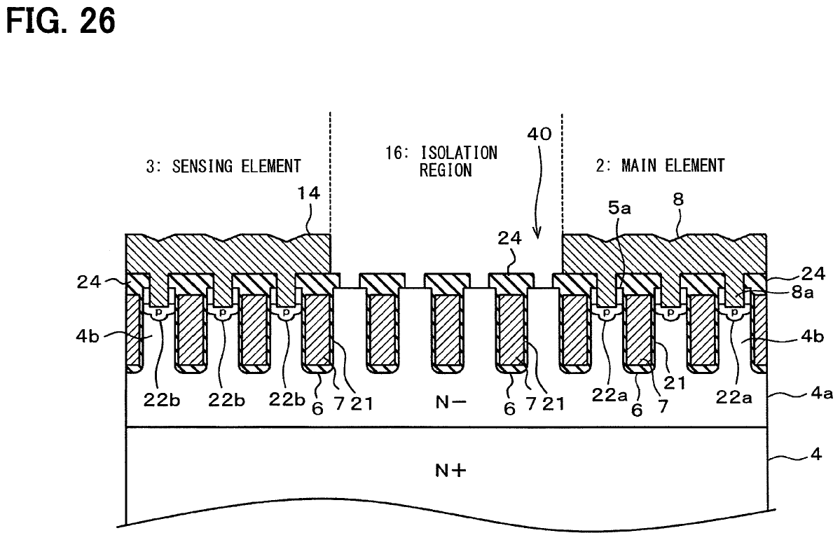

FIGS. 25 and 26 show a twelfth embodiment, and portions different from the first embodiment will be described below. In the embodiment, the isolation region 16 is provided with the LOCOS film 23 to isolate the elements in the first embodiment, whereas in a MOSFET 40 which is a semiconductor device, gate electrodes 7 are continuously formed in the isolation region 16.

In the isolation region 16, a trench is provided in common with the main element 2 and the sensing element 3, each gate electrode 7 is formed through an insulating film 21, and an insulating film 24 is formed on an upper surface of the gate electrode 7. Since the gate electrodes 7 are provided in common, no gate lead line 13 is provided.

Even with the configuration described above, similarly to the first embodiment, the resistance RA of the sensing element 3 can be set to be higher than the resistance RA of the main element 2, thereby being capable of obtaining a stable MOSFET 40 reducing a variation in the sensing ratio.

In the present embodiment, an example is shown in which a structure in which the gate electrodes 7 is provided in common in the isolation region 16 is applied to the first embodiment, but the structure can also be applied to the second to eleventh embodiments.

### Other Embodiments

It is to be noted that the present invention is not limited to the embodiments described above, and can be applied to various embodiments without departing from the gist thereof, and can be modified or expanded, for example, as follows.

The high resistance region of the sensing element 3 is not limited to that shown in the embodiments described above, and the effect can be obtained if a high resistance region is provided in a part of the region of the sensing element 3. In addition, the resistance of the source contact of the sensing element 3 may be increased or the wiring resistance may be increased.

Although the present disclosure has been described in accordance with the examples, it is understood that the present disclosure is not limited to such examples or structures. The present disclosure encompasses various modifications and variations within the scope of equivalents. In addition, various combinations and configurations, as well as other combinations and configurations that include only one element, more, or less, fall within the scope and spirit of the present disclosure.

What is claimed is:

1. A semiconductor device provided on a semiconductor substrate and comprising a main element of a gate driven type and a sensing element for current detection disposed across an isolation region, wherein
in a configuration in a forming region of the sensing element formed on the semiconductor substrate, at least a part of a resistance component contributing to a resistance of the sensing element has a resistance value higher than a resistance value of an equivalent configuration part of a resistance component contributing to a resistance of the main element.

2. The semiconductor device according to claim 1, wherein
a region in which at least one of the resistance component contributing to the resistance of the sensing element is set to be high is all or a part of the configuration in the forming region of the sensing element.

3. The semiconductor device according to claim 2, wherein
the region in which at least one of the resistance component contributing to the resistance of the sensing element is set to be high is a part or all of an outer peripheral region of the sensing element.

4. The semiconductor device according to claim 2, wherein
the region in which at least one of the resistance component contributing to the resistance of the sensing element is set to be high is a channel region of the sensing element.

5. The semiconductor device according to claim 2, wherein
the region in which at least one of the resistance component contributing to the resistance of the sensing element is set to be high is a drift region of the sensing element.
